(19) United States
(12) Patent Application Publication
(10) Pub. No.: US 2023/0207721 A1
(43) Pub. Date: Jun. 29, 2023

(54) Method For Fabricating A Photovoltaic Module Including Laser Cutting Of A Photovoltaic Label

(71) Applicant: Sono Motors GmbH, München (DE)

(72) Inventor: Mathieu BAUDRIT, Munich (DE)

(73) Assignee: Sono Motors GmbH, München (DE)

(21) Appl. No.: 18/002,888

(22) PCT Filed: Jun. 23, 2021
(86) PCT No.: PCT/EP2021/067179

§ 371 Date: Dec. 22, 2022

(30) Foreign Application Priority Data
Jun. 24, 2020 (GB) 2009642.6

(51) Int. Cl. H01L 31/18; H01L 31/048

(52) U.S. Cl. CPC H01L 31/18; H01L 31/048

(57) ABSTRACT

A method of fabricating a photovoltaic label for a photovoltaic module includes providing a solar cell arrangement including a plurality of photovoltaic cells and electrical connections interconnecting the photovoltaic cells; providing front and rear side polymeric stabilization foils; arranging the solar cell arrangement between the front and rear side polymeric stabilization foils; joining the front and rear side polymeric stabilization foil and the solar cell arrangement together for forming an intermediate product photovoltaic label in which the solar cell arrangement is encapsulated between the front and rear side polymeric stabilization foils; and cutting the intermediate product photovoltaic label along border regions thereof to form the photovoltaic label with final dimensions, wherein the intermediate product photovoltaic label is cut using a laser beam. The precisely dimensioned PV label may subsequently be supplied with a carrier structure e.g. using injection moulding in an in-mould labelling procedure for forming a PV module.

### FIELD OF THE INVENTION

The present invention relates to a method for preparing a photovoltaic module. Furthermore, the present invention relates to a method for preparing a photovoltaic label for a photovoltaic module. Particularly, the present invention may allow preparing photovoltaic modules with a non-planar shape which may be for example applied to or integrated into a body part of a car.

### BACKGROUND OF THE INVENTION

Photovoltaic modules comprise photovoltaic cells which may convert light energy into electric energy based on photovoltaic effects. Today, most commercial photovoltaic modules include photovoltaic cells which are manufactured based on semiconductor wafers such as silicon wafers. Wafer-based photovoltaic cells may be made with high conversion efficiencies at low costs. Furthermore, wafer-based photovoltaic cells may be manufactured using reliable industrial manufacturing processes.

In the following, the term “photovoltaic” may be abbreviated by “PV”. PV cells are also referred to as solar cells.

Conventionally, a PV module comprises a stack of several sheets and layers. Typically, a solar cell arrangement including a plurality of PV cells and electrical connections interconnecting the PV cells is interposed between a front side polymeric lamination foil and a rear side polymeric lamination foil, the lamination foils being for example thin sheets of EVA (ethylene vinyl acetate). As such lamination foils are generally thin and soft and therefore highly bendable, the lamination foils alone may not provide a sufficiently stable and rigid bases for the PV module. Therefore, additionally to the lamination foils, the PV module further comprises a carrier structure. Conventionally, such carrier structure is provided by one or more rigid sheets. For example, a front side sheet, i.e. a sheet at a front side of the PV module to be directed towards incident light, may be made with a transparent glass plate. Such front side sheet may cover, protect and stabilise the PV cells. Additionally or alternatively, the carrier structure may comprise a rear side sheet formed for example by a glass plate, a polymer foil or a metal sheet.

In fabricating a conventional PV module, the stack of one or more rigid sheets, the solar cell arrangement and the front and rear side polymeric lamination foils is prepared. Therein, the solar cell arrangement is interposed between the front and rear side lamination polymeric foils, thereby forming a sub-stack. This sub-stack is placed on one rigid sheet or between two rigid sheets, thereby forming the entire stack. Subsequently, the entire stack is heated to an elevated temperature. At such elevated temperature, the material of the polymeric lamination foils liquefies or at least comes to a viscous state such that the front side polymeric lamination foil and the rear side polymeric lamination foil are laminated to form a tight stack with the solar cell arrangement being comprised in between the two lamination foils and, furthermore, the polymeric lamination foils being joined with the one or more rigid sheets. Finally, a frame is typically arranged around the laminated entire stack. The frame provides additional mechanical stability and furthermore may serve for installing the PV module for example on top of a roof or on a pillar.

While such conventional fabricating of PV modules is well established, it may suffer from various deficiencies.

For example, laminating the solar cell arrangement to a carrier structure of one or more rigid sheets conventionally requires that the rigid sheets are planar. Accordingly, the entire PV module has a planar shape. However, there are various applications in which a PV module having a non-planar shape may be beneficial. For example, it has been proposed e.g. in an earlier patent application WO 2019/020718 A1 of the present applicant to integrate solar cells into a body part of a vehicle. Therein, the body part may have a non-planar shape and the PV module shall be placed on top of such body part or, preferably, the PV module shall be integrated into the body part or integrally forms the body part.

Furthermore, providing the PV module with a carrier structure formed for example by a glass sheet and/or a metal sheet may add substantial weight to the PV module and/or may add substantial costs for providing the glass sheet and/or metal sheet.

In order to overcome at least some of the above mentioned deficiencies, a new approach for manufacturing PV modules has been proposed by the present applicant in an earlier patent application PCT/EP2020/056972. Therein, a solar cell arrangement joined with a polymeric foil is integrated with a moulded layer formed by injection moulding. The moulded layer together with the integrated solar cell arrangement may form a PV module having a non-planar shape and may be manufactured at low costs. Features and characteristics of such approach may also apply to the method described herein and the content of the earlier patent application shall be incorporated in its entirety herein by reference.

However, it has been observed that, upon fabricating such moulded PV module, care has to be taken in order to avoid deficiencies resulting for example in a degraded conversion efficiency of the PV module and/or a decreased longevity of the PV module.

Accordingly, it may be an object to enable fabricating a PV module and overcome at least some of the above mentioned deficiencies. Particularly, it may be an object to enable fabricating a PV module with high reliability, high throughput, low costs, and/or a high quality of the final PV module.

### SUMMARY OF THE INVENTION AND OF EMBODIMENTS

At least some of these objects may be achieved with methods as defined in the independent claims. Preferred embodiments are defined in the dependent claims as well as in the subsequent specification.

According to a first aspect of the invention, a method for fabricating a photovoltaic label for a photovoltaic module is proposed. The method at least comprises the following method steps, preferably, but not necessarily, in the indicated order:
providing a solar cell arrangement including a plurality of photovoltaic cells and electrical connections interconnecting the cells;
providing a front side polymeric stabilisation foil and a rear side polymeric stabilisation foil;
arranging the solar cell arrangement between the front side polymeric stabilisation foil and the rear side polymeric stabilisation foil;
joining the front side polymeric stabilisation foil, the rear side polymeric stabilisation foil and the solar cell arrangement together for forming an intermediate product photovoltaic label in which the solar cell arrangement is encapsulated between the front and rear side polymeric stabilisation foils; and
cutting the intermediate product photovoltaic label along border regions thereof to form the photovoltaic label with final dimensions.

Therein, in the step of cutting, the intermediate product photovoltaic label is cut using a laser beam.

Preferably, the method additionally includes providing a front side polymeric lamination foil and a rear side polymeric lamination foil and arranging the solar cell arrangement between the front side polymeric lamination foil and the rear side polymeric lamination foil and between the front side polymeric stabilisation foil and the rear side polymeric stabilisation foil before joining the entire stack of lamination and stabilisation foils together.

According to a second aspect of the invention, a method for fabricating a photovoltaic module is proposed. The method at least comprises the following method steps: First, a photovoltaic label is prepared in accordance with a method according to an embodiment of the first aspect of the invention. Alternatively, a photovoltaic label which has previously been prepared in accordance with a method according to an embodiment of the first aspect of the invention may be provided. Subsequently, a carrier structure for carrying the photovoltaic label is prepared. Therein, the carrier structure is prepared with a polymer being in a mouldable condition. Particularly, the carrier structure is prepared such that the polymer forms a positive substance jointing with the rear side polymeric foil upon solidifying of the polymer.

Ideas underlying embodiments of the present invention may be interpreted as being based, inter alia and without restricting a scope of the invention, on the following observations and recognitions.

First, some basic ideas underlying embodiments of the present invention may be briefly summarised as follows:

As described in more detail in the applicant's earlier patent application PCT/EP2020/056972, a novel method of fabricating PV modules has been proposed. In this method, instead of conventionally laminating a planar stack of rigid sheets, polymeric lamination foils and an interposed solar cell arrangement in a common lamination procedure, a PV label is first fabricated by interposing the solar cell arrangement between front and rear side polymeric foils and then joining the front and rear side polymeric foils for encapsulating the solar cell arrangement. Then, the PV label is supplied with a carrier structure. Such carrier structure is generated by applying to the PV label a polymer which is temporarily brought into its mouldable condition for example via sufficiently heating the polymer. Upon subsequent cooling, the polymer for the carrier structure forms a positive substance jointing with the polymer of the rear side polymeric foil, such positive substance jointing being sometimes also referred to as substance-to-substance bonding. Preferably, the polymer for the carrier structure is applied by injecting the mouldable polymer into a mould with the PV label being also included in the mould. Similar processes in which a flexible structure such as a foil or a stack of foils is connected to a moulded carrier structure in a common moulding procedure are also known as in-mould labelling (IML). Upon adopting such IML, process for PV module fabrication, it has been found that the PV label generated in the first fabrication step needs to have very precise dimensions such that the PV label may e.g. be precisely accommodated within the IML mould. Typically, dimensions of the PV label should be set with tolerances being smaller than for example 1 mm. As, upon fabricating the PV label, it may generally not be guaranteed that the dimensions of the PV label may be set with a sufficient precision, the PV label may first be fabricated with excess dimensions and may then be cut to its final dimensions. It has been found that such cutting of the PV label may be a critical step. On the one hand, the PV label should be cut with sufficiently low dimensional tolerances, while the cutting procedure may be performed with sufficient cutting speed. On the other hand, the cutting action should not deteriorate the PV label in any critical manner. Particularly, it has been found that, while some conventional cutting procedures such as scissor cutting, saw cutting, waterjet cutting or other mechanical cutting technologies may provide for high cutting precision and/or high cutting speed, such cutting procedures may result in the final PV module deteriorating with regard to its efficiency and/or longevity. However, it has been found that using a laser beam for cutting an intermediate product PV label to its final dimensions may provide for very positive results. Underlying effects and advantages will be described in more detail further below.

Next, details, features and possible advantages of embodiments of the proposed method for fabricating the PV label and the proposed method for fabricating the PV module will be discussed:

In the method for fabricating the PV label, first, the solar cell arrangement and at least two polymeric stabilisation foils are provided and the solar cell arrangement is arranged between a front side polymeric stabilisation foil and a rear side polymeric stabilisation foil.

Therein, the solar cell arrangement includes a plurality of PV cells and electrical connections interconnecting these cells. The PV cells may be for example wafer-based solar cells, i.e. may be fabricated based on a semiconductor wafer, preferably crystalline semiconductor wafers. Particularly, according to an embodiment, the PV cells included in the solar cell arrangement are wafer-based silicon photovoltaic cells. Such wafer-based Si-PV cells may generally have e.g. a high efficiency of more than 15% (i.e. e.g. between 17% and 24%) and a high reliability. Furthermore, well established industrial processes exist for their fabrication. Such PV cells typically have lateral dimensions of between 50×50 mm² and 300×300 mm², mostly between 150×150 mm² and 200×200 mm², with a square shape, a rectangular shape, a round shape, a semi-round shape or any other shape. Furthermore, such PV cells generally have a thickness of more than 50 μm, typically between 100 μm and 300 μm. Having such thickness, such PV cells are relatively rigid, i.e. they may generally not be bent into small bending radii of e.g. less than their lateral dimensions. Each PV cell comprises electric contacts. The electric contacts of neighbouring PV cells are interconnected via electrical connections such that these PV cells may be electrically connected in series, in parallel or any combination of series and parallel connections. The electrical connections may be provided by one or more electrically conducting ribbons and/or one or more copper soldering between two adjacent photovoltaic cells, preferably between each two adjacent photovoltaic cells of a respective string. A plurality of interconnected PV cells forms the solar cell arrangement, sometimes also referred to as solar cell string. The solar cell arrangement may further comprise additional components such as external contacts via which the solar cell arrangement may be connected to an external electric circuit, such external contacts sometimes being referred to as forming part of a junction box. Furthermore, the solar cell arrangement may comprise for example bypass diodes or other electric components. Additionally, one or more release loops may be included in the solar cell arrangement.

The front side polymeric stabilisation foil and the rear side polymeric stabilization foil may enclose the interposed solar cell arrangement and may form a substrate and a superstrate, respectively, prior to performing e.g. a subsequent injection moulding step within for example an IML, procedure. For example, the polymeric stabilisation foils may have a thickness of between 500 μm and 5000 μm.

Accordingly, the polymeric stabilisation foils are generally substantially thicker than conventional polymeric lamination foils. Furthermore, the polymeric stabilisation foils may consist of another polymeric material than conventional polymeric lamination foils. Each of the stabilisation foils may adjoin and/or cover a part or an entirety of one of opposing surfaces of all of the photovoltaic cells in the solar cell arrangement.

It may be noted that, additionally to the polymeric stabilisation foils, polymeric lamination foils may be provided as being part of a front side foil stack and a rear side foil stack between which the solar cell arrangement is interposed. In such configuration, the solar cell arrangement generally adjoins the polymeric lamination foils at both of its opposing sides and the polymeric stabilisation foils serve as outer layers adjoining the polymeric lamination foils.

The polymeric stabilisation foils may be made with various polymeric materials such as polyetheretherketone (PEEK), polycarbonate (PC), polyethylenterephthalat (PET), polyamide (PA), acrylonitrile butadiene styrene (ABS) or a mix of them. Particularly, a material forming the polymeric stabilisation foil may be a thermoplastic material, i.e. a material which becomes plastic or viscous upon being heated to elevated temperatures. The front and rear side polymeric stabilisation foils may enclose the interposed solar cell arrangement and, upon being joined with each other, encapsulate the solar cell arrangement.

According to an embodiment, the front side polymeric stabilisation foil and the rear side polymeric stabilisation foil may have different physical characteristics. In other words, the polymeric stabilisation foil forming the substrate and the polymeric stabilisation foil forming the superstrate for the final PV label may differ with regard to their physical properties qualitatively and/or quantitatively. Accordingly, each polymeric stabilisation foil may be selected with physical characteristics such as to fulfil certain purposes.

For example, while the front side polymeric stabilisation foil may be required to have a highest possible optical transparency, the rear side polymeric stabilisation foil may not need such transparency. Accordingly, the front and the rear side polymeric stabilisation foils may differ with regard to their optical transparency and/or optical absorbance. As another example, one of the polymeric stabilisation foils may predominantly have to provide a mechanical stability for the PV label whereas the other polymeric stabilisation foil may predominantly have to serve for other purposes such as electric isolation, protection against direct contact to chemical substances, scratch protection, etc. For example, the rear side polymeric stabilisation foil and the front side polymeric stabilisation foil may have different rigidities. The rigidities may differ by more than 50%, more than 200% or even more than 500%. The rigidities of one of the stabilisation foils or, preferably, of both foils may be significantly smaller than the rigidity of a PV cell of the solar cell arrangement. Accordingly, in contrast to the PV cells, the foils may be substantially bendable, i.e. may be reversibly bent at a bending radius of e.g. less than 100 mm or even less than 10 mm.

More specifically, according to an embodiment, the front side polymeric stabilisation foil and the rear side polymeric stabilisation foil may have different thicknesses. For example, the rear side polymeric foil and the front side polymeric foil may have thicknesses which differ by more than 10%, more than 100%, more than 200% or even more than 500%. Having such different thicknesses, the physical characteristics of each of the polymeric stabilisation foils and/or of a laminate formed from such foils may be adapted to required purposes.

Furthermore, according to an embodiment, the front side polymeric stabilisation foil and the rear side polymeric stabilisation foil may comprise or consist of different materials. For example, while the rear side polymeric stabilisation foil may be provided with a first material adapted for providing first physical characteristics, the front side polymeric stabilisation foil may be provided with a second material adapted for providing other physical characteristics. For example, the materials of the front and rear side polymeric stabilisation foils may differ with regard to their optical characteristics. Accordingly, the front and rear side foils may have different colours or, more generally, different light absorbing characteristics. The materials of the front and rear side polymeric stabilisation foils may differ with regard to their type of polymer and/or with regard to a provision of additives influencing physical characteristics of such polymer.

However, it is to be noted that the front and rear side polymeric stabilisation foils may also be provided with identical characteristics, i.e. may have identical thicknesses, materials and/or other physical properties. As such, both polymeric stabilisation foils may be provided at large volumes, low cost and/or simple logistics requirements.

After having arranged the solar cell arrangement between the two polymeric stabilisation foils with each of its solar cells being positioned laterally next to at least one neighbouring solar cell and interposed between the front side polymeric stabilisation foil and the rear side polymeric stabilisation foil, the front and rear side polymeric stabilisation foils are joined with each other. Upon such mechanical joining, both polymeric stabilisation foils including the interposed solar cell arrangement form an intermediate product which is referred herein to as “intermediate product photovoltaic label”. In such intermediate product photovoltaic label, the solar cell arrangement is encapsulated between the front and rear side polymeric stabilisation foils. In other words, both polymeric stabilisation foils are joined with each other in such manner that the solar cell arrangement is tightly included in the stack or compound formed with both opposing polymeric stabilisation foils. Preferably, the front and rear side polymeric stabilisation foils are joined such as to form a positive substance jointing with each other.

Particularly, according to an embodiment, in the step of joining, the front side polymeric stabilisation foil, the rear side polymeric stabilisation foil and the solar cell arrangement are joined together by at least one of an application of heat and a lamination process. In other words, after having arranged e.g. the rear side polymeric stabilisation foil, the solar cell arrangement and finally the front side polymeric stabilisation foil on top of each other in a lose manner, these stacked layers may be interconnected by mechanically joining with each other. Optionally and preferably, additional polymeric lamination foils are interposed between the stabilising foils and the solar cell arrangement at both opposing sides of the solar cell arrangement. The joining may be induced for example by applying sufficient heat to the stack such that the polymeric material of the polymeric foils becomes this viscous and/or sticky. Accordingly, upon such temporary application of heat, the polymeric foils may mechanically interconnect with each other and/or with the interposed solar cell arrangement. Such procedure is sometimes referred to as lamination procedure. As a result of such lamination procedure, the front and rear side polymeric foils and, optionally, also the solar cell arrangement are integrally joined with each other in a positive substance jointing. However, the lamination procedure may alternatively or additionally include other measures for joining the polymeric foils such as for example applying a glue or adherent at an interface between the polymeric foils and/or at an interface between one of the polymeric foils and the solar cell arrangement.

The resulting intermediate product photovoltaic label as well as the final photovoltaic label typically comprise various characteristics. For example, the solar cells of the solar cell arrangement included therein are protected at least to a certain degree against mechanical, electrical and/or chemical influences potentially damaging the solar cells. Furthermore, in the laminate forming the photovoltaic label, the solar cells of the solar cell arrangement are stabilized and mechanically interconnected with each other via the polymeric foils enclosing the entire solar cell arrangement. Accordingly, the entire photovoltaic label may be easily handled for example during a subsequent PV module fabrication procedure. However, the PV label alone generally does not have sufficient mechanical stability and/or rigidity required by a final PV module. In other words, the photovoltaic label is generally highly bendable at least in areas laterally in between neighbouring solar cells. Particularly, the photovoltaic label alone is generally not self-supporting. Accordingly, as further described in more detail below, the photovoltaic label may have to be provided with a carrier structure for forming a final product forming a PV module.

In conventional PV module fabrication, the polymeric lamination foils forming part of the encapsulation are generally provided with some excess lateral dimensions such as to sufficiently overlap the solar cell arrangement and sufficiently laterally extend beyond the outermost borders of the solar cells comprised therein. For example, the polymeric lamination foils may extend beyond the outermost borders of the solar cells by several millimetres. In such conventional encapsulation, even some misalignment between both polymeric foils generally does not negatively affect the final PV module. Particularly, in most conventional PV modules, the frame carrying the laminate of stacked rigid sheets, polymeric foils and solar cell arrangement typically covers at least some millimetres of such laminate at its circumferential borders such that any misalignment of the polymeric foils may be covered by such frame.

However, in the PV module fabrication proposed herein, particularly in PV module fabrication based on in-mould labelling, it may be necessary to provide the PV label with very accurate lateral dimensions. Particularly, an accuracy in which the PV label is to be provided for subsequent PV module fabrication may only accept tolerances in lateral dimensions of less than a certain predetermined limit. Such predetermined limits may be for example equal or smaller than 1 mm in one or each lateral direction. If tolerances in lateral dimensions exceed such limits, various problems may occur during subsequent fabrication steps. For example, upon injecting polymeric material in its mouldable condition in a subsequent injection moulding step, insufficient accuracy of the dimensions of the PV label to be moulded together with this injected polymeric material may result in an insufficient product quality of the final PV module. Particularly, in case the PV label is to be accommodated at a specific area within a mould during such in-mould labelling process, a PV label having lateral dimensions being excessively smaller than tolerated defined lateral dimensions may result in mouldable polymeric material reaching for example areas of the PV label which shall not be covered by such mouldable polymeric material. Particularly, excessively small lateral dimensions of the PV label may result in mouldable polymeric material reaching the front side of the PV label during in-mould labelling, thereby disturbing a functionality and/or appearance of the final PV module. Accordingly, the PV label should be provided with very precise lateral dimensions, these dimensions deviating from predefined dimensions at most by acceptable tolerances.

The front side polymeric stabilisation foil and the rear side polymeric stabilisation foil may originally not be provided with predefined dimensions intended or required e.g. for subsequent PV module fabrication steps. Generally, the polymeric foils are originally provided with some excessive lateral dimensions. However, even assuming that the polymeric foils could be provided with the exact predefined dimensions, there may be a risk that during preceding method steps such as the step of arranging the solar cell arrangement in between the front and rear side polymeric foils and/or the step of joining the polymeric foils for forming the intermediate product photovoltaic label, the front and rear side polymeric foils may be slightly displaced, thereby becoming slightly misaligned with respect to each other. Accordingly, there may be a need to cut the intermediate product photovoltaic label in order to form the PV label with final dimensions, these final dimensions sufficiently corresponding to the intended predefined dimensions.

Generally, various cutting techniques may be available for cutting the polymeric stabilisation foils of the intermediate product PV label. For example, the polymeric foils could be cut using some kind of scissors or a blade of a knife. In industrial applications, such scissors or blade could be handled by a machine or robot. Alternatively, an automated sawing machine or dicing machine may be used for cutting the intermediate product PV label. As a further alternative, cutting the intermediate product PV label using a high pressure water jet is conceivable.

However, it has been observed by the applicant that all such approaches for mechanically cutting the polymeric stabilisation foils of the intermediate product PV label may result in deteriorated characteristics for the final PV module fabricated from such PV label. Particularly, it has been observed that mechanical degradations in the PV label may result from such mechanically cutting. The mechanical degradations may then deteriorate for example a mechanical stability, an electrical efficiency and/or a longevity of the final PV module.

Particularly, it has been observed by the applicant that mechanically cutting the intermediate product PV label may result in micro-vibrations or other mechanical forces acting onto the stack of polymeric foils of the intermediate product PV label in an area right next to a cutting line. In other words, upon mechanically cutting, forces may be applied to the stack of polymeric foils which have previously been joined with each other. As such forces may generally occur at or close to the cutting line which later on forms the outer border of the final PV label, the PV label is specifically susceptible to local damaging. It has been observed by the applicant that mechanically cutting the intermediate product PV label may result in so-called micro-delaminations, i.e. in small areas in which the former joint between the front and rear side polymeric stabilisation foils is locally released, i.e. both polymeric foils are locally peeled-off from each other. Accordingly, at such micro-delaminations, the front and rear side polymeric foils are no more sufficiently joined with each other after the mechanical cutting procedure. For example, cavities may occur at such micro-delaminations. It has been observed by the applicant that the micro-delaminations or other mechanical defects induced by the mechanical cutting may result in problems during subsequent PV module fabrication steps. Particularly, it has been observed that during subsequent injection moulding for example in an in-mould labelling procedure, a lacking adherence between the front and rear side polymeric foils due to micro-delaminations may result in insufficient moulding products. Specifically, local delaminations in the PV label may deteriorate the quality of the final PV module. Overall, the final moulded PV module may suffer from the mechanical damaging induced during mechanically cutting the intermediate product photovoltaic label.

In order to avoid such problems and deficiencies, it is suggested to apply a specific non-mechanical, i.e. contactless, cutting technique for cutting the intermediate product PV label. Particularly, it is suggested to use a laser beam for cutting the intermediate product PV label. Therein, a laser beam is a high-intensity focused beam of light. The laser beam may be emitted by a laser source such as a gas laser, a solid-state laser or a laser diode. During a cutting procedure, the laser beam may be guided along a guidance line defining a resulting cutting-edge. Accordingly, such guidance line may define the final dimensions and/or contour of the PV label. Particularly, the guidance line may include linear portions and/or curved portions. Accordingly, the PV label may be cut to any arbitrary contour. Thus, the final PV module comprising such PV label may have any arbitrary geometry and contour. Particularly, the PV label as well as the PV module may have a curved shape.

In order to realise satisfying cutting results, characteristics of the laser beam may be specifically adapted for cutting the intermediate product PV label. The characteristics of the laser beam may include a variety of physical properties such as an intensity of the laser light, a spectrum or wavelength of the laser light, a beam width or beam shape of the laser beam, a laser beam displacement velocity, a time dependence of the emitted laser light, i.e. whether the laser beam is continuously emitted or emitted in pulses having a certain pulse duration, etc. The characteristics of the laser beam may be adapted such that, on the one hand, fast and precisely cutting the PV label is enabled while, on the other hand, a generated cutting edge shows intended characteristics.

For example, according to an embodiment, the front side polymeric stabilisation foil and the rear side polymeric stabilisation foil may be cut in a common cutting action using the laser beam. In other words, the characteristics with which the laser beam is applied to the PV label during the cutting action may be set such that both, the front side polymeric stabilisation foil as well as the rear side polymeric stabilisation foil are simultaneously cut by the laser beam in a single cutting process. By cutting both, the front and the rear side polymeric stabilisation foil in a single step, the entire cutting process may be accelerated. Furthermore, such simultaneous cutting of both polymeric stabilisation foils may improve characteristics of the resulting cutting-edge.

For such cutting characteristics, physical properties of the laser beam such as its intensity, its wavelength or spectrum and its cross-section may be set for example such that an energy included in the laser beam is absorbed not only at one of the surfaces of the PV label were the laser beam first impinges but preferably is absorbed and/or distributed throughout the entire thickness of the PV label. For example, the wavelength or spectrum of the laser beam may be adapted to the polymeric material of the polymeric foils such that the polymeric stabilisation foils exhibit an absorption to the laser beam light which is not to strong and not too weak. Particularly, on the one hand, the absorption to the laser beam light should not be too strong, as otherwise the laser beam light would almost completely be absorbed close to an impingement surface of the PV label, thereby only superficially heating the PV label. However, on the other hand, the absorption to the laser beam light should not be too weak as otherwise the laser beam would hardly be absorbed along its transmission through the PV label. Instead, the laser beam characteristics should be selected depending on optical characteristics of the material of the polymeric foils and should be set such that a significant part of the laser beam is successively absorbed upon the laser beam being transmitted through the entire stack including the front side and the rear side polymeric foils of the PV label.

According to an embodiment of the invention, the laser beam may be applied with physical characteristics which are selected such that, in the step of cutting, the front side polymeric stabilisation foil and the rear side polymeric stabilisation foil are joined as a positive substance jointing in an area adjoining a cutting edge due to energy applied by the laser beam. Expressed differently, characteristics of the laser beam may not only be adapted such that the PV label is locally cut upon absorption of the laser beam but also such that, as a result of such laser beam absorption, the front side polymeric foil and the rear side polymeric foil are temporarily heated such that finally a positive substance jointing is established between both polymeric stabilisation foils. Particularly, such positive substance jointing shall be established or supported in an area adjoining the location where the laser beam cutting has been done, i.e. in an area at and/or adjoining the location where the laser beam is absorbed in the PV label and, accordingly, the cutting-edge is generated.

In other words, as a positive side effect during the cutting action, the cutting laser beam should have characteristics such that the front and rear side polymeric foils are locally and temporarily modified such that a positive substance jointing results at the cutting edge. Such local and temporarily modification may for example mean that the material of the front and rear side polymeric foil may be modified due to the absorption of the laser beam. For example, laser beam absorption may result in temporarily heating this material such that it locally becomes viscous. Due to such temporarily heating, the material of the rear side polymeric foil and the material of the front side polymeric foil may locally merge, i.e. may build up a common phase, thereby resulting in the intended positive substance jointing upon subsequent cooling of the material. Expressed differently, a simultaneous cutting and sealing action may be carried out for the front and rear side stabilisation foils by controlling the laser-beam characteristics to cut both foils in contact while leaving a welded region at an edge of the cut.

Particularly, according to an embodiment of the invention, the front side polymeric stabilisation foil and the rear side polymeric stabilisation foil may each consist of a polymeric material and the laser beam may be applied with physical characteristics which are selected such that, in the step of cutting, the front side polymeric stabilisation foil and the rear side polymeric stabilisation foil are temporarily heated to a maximum temperature in an area adjoining a cutting edge due to energy applied by the laser beam, the maximum temperature being between a glass transition temperature and a autoignition temperature of the polymeric material of one or both of the front side polymeric foil and the rear side polymeric foil.

In other words, characteristics of the cutting laser beam may be adapted such that, when the laser beam is absorbed in the polymeric material of the PV label, this polymeric material is locally heated beyond its glass transition temperature. Therein, the glass transition temperature of a material characterises a range of temperatures over which a glass transition occurs. The glass transition (sometimes also referred to as glass-liquid transition) is a gradual and reversible transition in amorphous materials from a hard and relatively brittle “glassy” state into a viscous or rubbery state as the temperature is increased. Preferably, the characteristics of the cutting laser beam may be adapted such that, in the cutting action, the polymeric material is locally heated beyond its Vicat softening temperature. The Vicat softening temperature or Vicat hardness is a determination of the softening point for materials that have no definite melting point, such as plastics. Standards to determine a Vicat softening point include ASTM D 1525 and ISO 306. Generally, the glass transition temperature and the Vicat softening temperature are lower than a melting temperature of the same material when the material being in its crystalline state. By heating the polymeric material of the front and/or rear side polymeric foil beyond its glass transition temperature or its Vicat softening temperature, this polymeric material becomes mouldable and/or sticky and may therefore combine with the polymeric material of the other polymeric foil. Upon subsequent cooling, the polymeric material then forms the intended positive substance jointing between both polymeric foils.

However, care should be taken upon selecting the laser beam characteristics such that the maximum temperature achieved upon laser beam absorption remains lower than an autoignition temperature of the polymeric material for both, the polymeric material of the front side polymeric foil as well as the polymeric material of the rear side polymeric foil. Such autoignition temperature, which is sometimes also referred to as kindling point of a substance, is the lowest temperature at which it spontaneously ignites in a normal atmosphere without an external source of ignition such as a flame or spark. This temperature is generally required to supply the activation energy needed for combustion. By keeping the temperature in the polymeric material below its autoignition temperature during the laser beam cutting action, deterioration of the resulting cutting-edge due to local burning or charing of the polymeric material may be avoided.

Preferably, the laser beam is applied with physical characteristics which are selected such that, in the step of cutting, the front side polymeric stabilisation foil and the rear side polymeric stabilisation foil are temporarily heated to a maximum temperature which is below a melting temperature of the polymeric material of at least one of the front side polymeric stabilisation foil and the rear side polymeric stabilisation foil.

In other words, the cutting action should preferably be performed with a laser beam the characteristics of which are specifically adapted such that upon its absorption, the polymeric material of the front and/or rear side polymeric foil is heated to a temperature between the glass transition temperature and the melting temperature of this material. In such temperature range, the polymeric material temporarily becomes viscous and sticky while, however, not becoming completely liquid. Accordingly, any flowing or pouring of liquefied polymeric material may be avoided and the resulting positive substance jointing between the foils may be of very high quality.

Laser beam characteristics which influence the degree of heating the polymeric material absorbing the laser beam generally comprise, inter-alia, a laser beam spectrum, a laser beam intensity, a laser beam displacement velocity and a time dependence of the emitted laser beam intensity in case the laser beam is not emitted continuously. The latter parameter is sometimes also referred to as pulse length and pulse duration. These parameters should be set such that upon absorbing the laser beam sufficient energy is introduced into the polymeric material for locally heating and thereby glassifying it. Accordingly, for example the laser beam intensity and/or a pulse length should be sufficiently high such that enough energy is absorbed in the polymeric material before spreading the thermal energy for example by thermal conduction. However, excessive heat generation should be avoided in order to prevent igniting the polymeric material. Furthermore, very high laser beam intensity combined with very short laser pulses may result in a very high energy absorption in a short time which may result in ablating polymeric material instead of heating it. Accordingly, such high-intensity lasering regime might have to be avoided as in such high-intensity regime, polymeric material is ablated and disappears before sufficient thermal energy is transmitted to neighbouring material. Thus, any temporarily glassifying of polymeric material may not occur at such high-intensity regime such that, finally, no positive substance jointing between the polymeric foils may be established.

As a result of suitably selecting the laser beam parameters, the polymeric material of the front and rear side polymeric stabilisation foils may be heated during the cutting action to a degree such that, after subsequent cooling down, a very stable positive substance jointing may be established between both foils. Therein, a joint or adherence between both foils may not be deteriorated during the cutting action. Instead, in a best case scenario, such joint or adherence of the foils in an area adjacent to the cutting edge may even be enhanced as a result of the temporary heating action accompanying the cutting action, thereby laser welding both stabilisation foils into a positive substance jointing. Accordingly, any micro-delaminations at the cutting edge may be avoided and the cutting edge may even be stabilised by the cutting action.

Furthermore, it has been found that it may be beneficial or even be required to at least slightly press both polymeric stabilisation foils against each other during the laser cutting and welding procedure. Accordingly, mechanical forces might have to be applied in opposite directions to both stabilisation foils while the laser beam is cutting these foils, at least in an area where the foils are currently irradiated with the laser beam.

According to an embodiment of the invention, the intermediate product photovoltaic label is cut using the laser beam such as to form the photovoltaic label with final dimensions with a lateral tolerance of less than 1 mm, preferably less than 0.2 mm, with regards to predefined dimensions.

Expressed differently, during the laser cutting process, the laser beam may be formed, focused, guided and/or displaced with a very high accuracy which allows very precisely establishing the resulting cutting-edge. Accordingly, using such high precision laser cutting, final dimensions of the PV label may be achieved with very low lateral tolerances. Accordingly, as the final dimensions of the PV label may precisely correspond to intended predefined dimensions, the PV label may for example be positioned very precisely within tools such as for example in-mould injection moulding equipment upon subsequent fabrication steps.

For example, in an embodiment of the method for PV module fabrication, upon the preparing of the carrier structure, the polymer being in the mouldable condition may be injected into a mould. Therein, the mould typically comprises a recess having specific recess dimensions. Upon the preparing of the carrier structure, the photovoltaic label may then be arranged in the recess of the mould after having been cut to the final dimensions during the preparing of the photovoltaic label, the final dimensions being equal or less than 1 mm smaller than the recess dimensions.

In other words, in an injection moulding technique which largely resembles to the in-mould labelling technique, the PV label previously prepared with very precise dimensions may be precisely arranged at an intended location within a moulding tool. Therein, the PV label may be tightly accommodated within a recess. Subsequently, the polymer is introduced into the moulding tool, wherein the polymer is brought to its mouldable condition for example by suitably heating the polymer. Polymers which are suitable for such injection moulding may include thermoplastics, thermosets and elastomers. Materials such as polypropylene (PP), polycarbonate (PC), polyethylene (PE), polytetrafluoroethylene (PTFE), polyoxymethylene (POM), acrylonitrile butadiene styrene (ABS), a polyaryletherketone (PAEK), polyether ether ketone (PEEK), copolymers of polypropylene and ethylene, epoxy, phenolic, nylon, polystyrene (PS), polyamide (PA) and/or silicone (or any combination thereof) may be used for the injection moulded carrier structure. A cavity of the moulding tool defining the final shape of the moulded carrier structure may have any arbitrary shape. Particularly, such cavity may have curved surfaces. Accordingly, the final PV module including the carrier structure and the PV level may have a complex shape and, particularly, may have a shape with curved surfaces corresponding for example to a functional component such as an outer body part of a vehicle.

Furthermore, according to an embodiment of the PV module fabrication method, upon the preparing of the carrier structure, the polymer in its mouldable condition is applied to the photovoltaic label exclusively at an exposed surface of the rear side polymeric stabilisation foil. In other words, for example in generating the carrier structure using an IML procedure, the PV label may be precisely dimensioned and precisely positioned within the moulding tool such that upon injecting the mouldable polymer into the moulding tool, this polymer exclusively contacts the PV label at its rear side while not reaching the front side of the PV label. Such selectively forming the carrier structure and joining the material of the carrier structure with the PV label exclusively at one side allows for preparing a PV module having a strong mechanical structure, a high conversion efficiency, an aesthetic appearance and/or a satisfying longevity.

According to an embodiment, the front side polymeric stabilisation foil and/or the rear side polymeric stabilisation foil may comprise at least one marker. Therein, during the step of cutting the intermediate product PV label, the laser beam may be guided with reference to the at least one marker. In other words, at least one marker may be provided for example at a surface of the PV label at a predefined position. Such marker may serve as a reference location such that the laser beam may be positioned and/or displaced relative to such marker during the cutting action. Preferably, multiple markers are provided as the PV label for guiding the laser beam. Each marker may mark one position, line or area on the PV label. The markers may have various characteristics and may be established using various techniques. For example, the markers may be formed such as to be visually detectable. For example, the markers may be areas on the PV label having other optical characteristics than neighbouring areas. For example, at a marker, an optical absorbance and/or reflectivity may be different compared to adjacent areas. The marker may be formed by a coloured or de-coloured area or symbol on the PV label, by an indentation or a protrusion at the PV label and/or by similar means. The visual marker may be detected for example using a sensor, a camera or another type of detector provided in a laser cutting tool and the laser beam may then be positioned by the laser cutting tool with reference to the detected marker.

It shall be noted that possible features and advantages of embodiments of the invention are described herein partly with respect to a method for fabricating a PV label and partly with respect to a method for fabricating a PV module using such PV label. One skilled in the art will recognize that the features may be suitably transferred from one embodiment to another and features may be modified, adapted, combined and/or replaced, etc. in order to come to further embodiments of the invention.

### BRIEF DESCRIPTION OF THE DRAWINGS

In the following, advantageous embodiments of the invention will be described with reference to the enclosed drawing. However, neither the drawing nor the description shall be interpreted as limiting the invention.

FIG. 1 shows a cross-sectional view through a PV label during a fabrication method according to an embodiment of the invention.

FIG. 2 shows a top view onto a PV label.

FIG. 3 shows a cross-sectional view through a PV label during a cutting step of a fabrication method according to an embodiment of the invention.

FIG. 4 shows a cross-sectional view through an in-mould labelling tool for fabricating a PV module according to an embodiment of the invention.

The figures are only schematic and not to scale. Same reference signs refer to same or similar features.

### DESCRIPTION OF ADVANTAGEOUS EMBODIMENTS

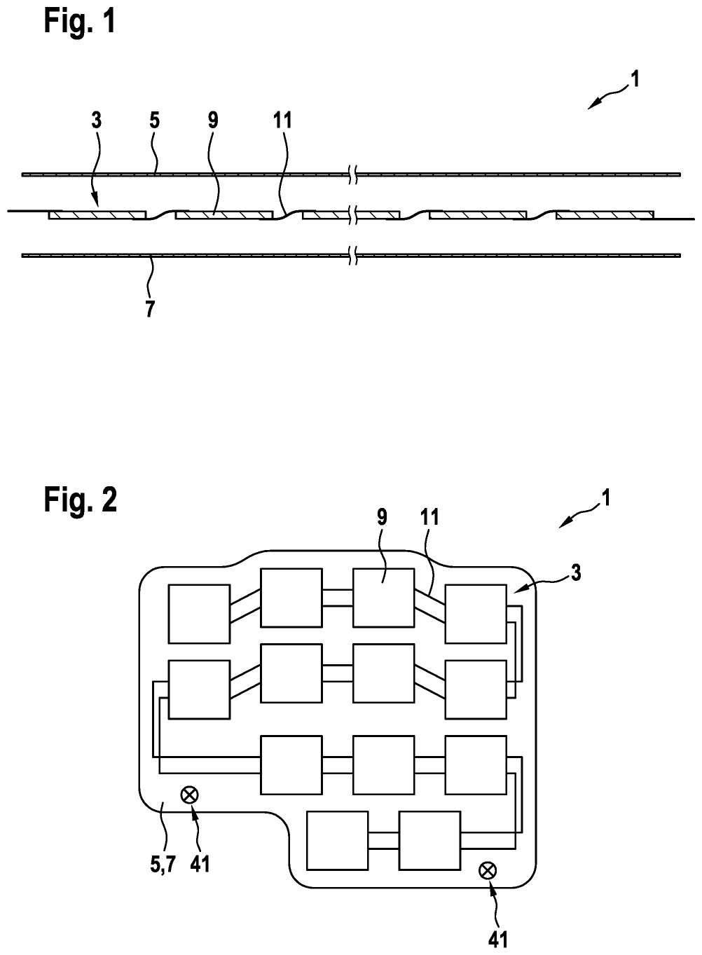

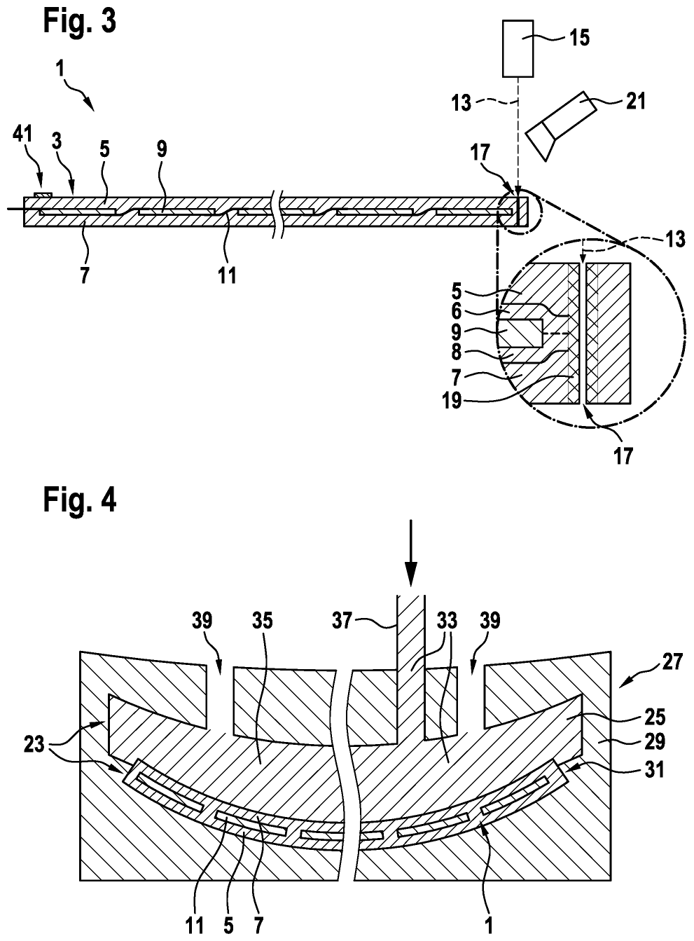

FIG. 1 and FIG. 3 show cross sections of a PV label 1 in subsequent steps of a fabrication method for preparing the PV label 1. FIG. 2 shows a top view onto an exemplary PV label 1. As visualized in FIG. 2, the PV label 1 may have a complex shape with curved surfaces and/or a curved contour.¶

At the beginning of the fabrication of the PV label 1, a solar cell arrangement 3, a front side polymeric stabilisation foil 5 and a rear side polymeric stabilisation foil 7 are provided. Additionally, a front side polymeric lamination foil 6 and a rear side polymeric lamination foil 8 may be provided (shown only in the zoomed visualisation in FIG. 3). The solar cell arrangement 3 comprises a plurality of PV cells 9 which are interconnected via electrical connections 11. The PV cells 9 are arranged next to each other and are interconnected in series and/or in parallel. The solar cell arrangement 3 may comprise further components such as bypass diodes, junction boxes, etc. (not explicitly shown).

After having stacked the front side polymeric stabilisation foil 5 on top of the solar cell arrangement 3 and the rear side polymeric stabilisation foil 7 underneath the solar cell arrangement 3, with the front and rear side polymeric lamination foils 6, 8 additionally being interposed between the solar cell arrangement 3 and each of the front and rear side stabilisation foils 5, 7, the entire stack is subjected to a lamination procedure. In such lamination procedure, the stack is heated to an elevated temperature of for example between 60° C. and 250° C. and set under pressure. As a result of such lamination procedure, the front side polymeric stabilisation foil 5, the rear side polymeric stabilisation foil 7 and the interposed solar cell arrangement 3 are joined with each other as the polymeric stabilisation foils 5, 7 and/or the interposed polymeric lamination foils 6, 8 became sticky at the elevated temperature and adhere to each other and to the solar cell arrangement 3. Accordingly, the front side polymeric stabilisation foil 5, the rear side polymeric stabilisation foil 7 and the interposed solar cell arrangement 3 form the PV label 1 as an entity which may be easily handled during subsequent processing steps and in which the solar cell arrangement 3 is protected against mechanical, electrical and/or chemical attacks.

Generally, the front side polymeric stabilisation foil 5 and the rear side polymeric stabilisation foil 7 are initially provided with excess dimensions, i.e. with dimensions which exceed intended final dimensions. Accordingly, after having joined the polymeric stabilisation foils 5, 7 and the solar cell arrangement 3 to form an intermediate product PV label 1, the lateral dimensions of such PV label 1 have the be adapted to the intended final dimensions by suitably cutting the intermediate product photovoltaic label 1.

As schematically shown in FIG. 3, such cutting is done using a laser beam 13. The laser beam 13 is emitted by a laser source 15. The laser beam 13 is precisely directed and guided along an intended line which shall form a cutting edge 17 for the final PV label 1. Therein, the cutting-edge 17 may correspond to the outer contour of the PV label 1 with intended final dimensions. The laser beam 13 may be guided along the intended line with lateral tolerances being smaller than 1 mm. For precisely guiding the laser beam 13, markers 41 provided for example at an outer surface of one of the polymeric foils (5, 7) may be detected and the laser beam 13 is then positioned relative to these markers 41.

Characteristics of the laser source 15 and its emitted laser beam 13 are specifically adapted to the functionality of cutting and simultaneously welding and thereby sealing the PV label 1 along a laser cutting edge. Accordingly, a laser beam intensity and a laser beam spectrum are selected such that the laser beam 13 is suitably absorbed upon being at least partially transmitted through the PV label 1 and its front and rear side polymeric foils 5, 7. Also other laser beam characteristics such as a laser beam intensity, a laser beam power and/or a pulse length and a pulse duration in case that the laser source 15 emits the laser beam 13 in a pulsed regime may be suitably selected.

The laser beam characteristics are preferably set such that, on the one hand, both, the front and the rear side polymeric stabilisation foils 5, 7 are cut by the laser beam 13 in a single common cutting action. On the other hand, the laser beam characteristics are set such that the polymeric material of the front and/or rear side polymeric stabilisation foils 5, 7 is temporarily heated upon absorption of the laser beam 13 to such an extent that, in an area 19 adjoining the cutting edge 17, the polymeric material reaches an elevated temperature being between the glass transition temperature and the autoignition temperature, preferably between the glass transition temperature and the melting temperature, of the polymeric material of at least one of the stabilisation polymeric foils 5, 7.

Accordingly, as a result of the absorption of the laser beam 13 during the cutting action, the area 19 adjoining the cutting edge 17 is temporarily glassyfied, i.e. brought into a glassy or partly molten condition. Therefore, after subsequently cooling down this area 19, a reliable and strong positive substance jointing is established between the front and rear side polymeric stabilisation foils 5, 7. Consequently, a risk for an occurrence of micro-delaminations between both polymeric foils 5, 7 may be minimized.

For example, the laser source 15 and its laser beam 13 may be provided with the following characteristics: The laser source 15 may be for example a CO₂ laser or CO laser. Alternatively, other types of laser sources 15 may be used. The laser beam 13 may be emitted at a wavelength of for example between 400 nm and 100 μm preferably between 1 μm and 20 μm. For example, a CO₂ laser typically emits radiation at 10.6 μm. The laser beam 13 may typically be provided with a power of between 10 W and 10 kW. The beam may be continuously emitted or pulsed. A pulse length may be in a range of sub-microseconds to a few milliseconds. A pulse frequency may be in a range of 1 Hz to some hundred Hz. With such characteristics, the laser beam 13 may provide for a smooth and strong joint at the cutting edge 17 for the PV label 1 formed with the front and rear side polymeric stabilisation foils 5, 7 having thicknesses of between 200 μm and 5000 μm and being formed from a polymeric materials such as for example polypropylene (PP), polycarbonate (PC), polyethylene (PE), polytetrafluoroethylene (PTFE), polyoxymethylene (POM), acrylonitrile butadiene styrene (ABS), a polyaryletherketone (PAEK), polyether ether ketone (PEEK), copolymers of polypropylene and ethylene, epoxy, phenolic, nylon, polystyrene (PS), polyamide (PA). It shall be noted that the proposed characteristics and parameters are exemplary only.

In order to avoid potential problems during the laser cutting action, combustible and/or non-combustible gasses typically occurring upon heating polymer material may be extracted by suction using an exhaust 21.

Upon having prepared the PV label 1 with its final dimensions, a PV module 23 may be fabricated by preparing a carrier structure 25 for carrying the PV label 1. As schematically shown in FIG. 4, the PV label 1 may be inserted into a mould 29 of an injection moulding tool 27. The mould 29 comprises a recess 31. The recess 31 has recess dimensions. The final dimensions of the PV label 1 have been previously cut such that they precisely correspond to the recess dimensions. Accordingly, the PV label 1 may be tightly inserted into the recess 31. In a subsequent injection moulding procedure, a polymer 33 is inserted via an inlet 37 into a cavity 35 of the mould 29. Excess air may be released from the cavity 35 via outlets 39. The cavity 35 extends adjacent to the recess 31, i.e. adjacent to the PV label 1 arranged in this recess 31. Accordingly, the polymer 33 may come into close mechanical contact with one surface of the PV label 1, preferably with a rear side surface of the rear side polymeric foil 7 of the PV label 1. The polymer 33 is heated to an elevated temperature being e.g. higher than the glass transition temperature of the polymer 33 such that it becomes mouldable. Accordingly, upon subsequent cooling, the polymer 33 may form the self-supporting carrier structure 25 for the PV module 23, the polymer 33 of such carrier structure 25 forming a positive substance jointing with at least one of the front and rear side polymeric stabilisation foils 5, 7 of the PV label 1.

Finally, it should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

### LIST OF REFERENCE NUMERALS

1 PV label

3 solar cell arrangement

5 front side polymeric stabilisation foil

6 front side polymeric lamination foil

7 rear side polymeric stabilisation foil

8 rear side polymeric lamination foil

9 PV cell

11 electrical connection

13 laser beam

15 laser source

17 cutting-edge

19 area adjoining to the cutting-edge

21 exhaust

23 PV module

25 carrier structure

27 moulding tool

29 mould

31 recess

33 polymer

35 cavity

37 inlet

39 outlet

41 marker

1-14. (canceled)

15. Method for fabricating a photovoltaic label for a photovoltaic module, the method at least comprising:
providing a solar cell arrangement including a plurality of photovoltaic cells and electrical connections interconnecting the photovoltaic cells;
providing a front side polymeric stabilization foil and a rear side polymeric stabilization foil;
arranging the solar cell arrangement between the front side polymeric stabilization foil and the rear side polymeric stabilization foil;
joining the front side polymeric stabilization foil, the rear side polymeric stabilization foil and the solar cell arrangement together for forming an intermediate product photovoltaic label in which the solar cell arrangement is encapsulated between the front and rear side polymeric stabilization foils; and
cutting the intermediate product photovoltaic label along border regions thereof to form the photovoltaic label with final dimensions,
wherein, in the step of cutting, the intermediate product photovoltaic label is cut using a laser beam,
wherein the laser beam is applied with physical characteristics which are selected such that, in the step of cutting, the front side polymeric stabilization foil and the rear side polymeric stabilization foil are joined as a positive substance jointing in an area adjoining a cutting edge due to energy applied by the laser beam.

16. Method according to claim 15,
wherein the front side polymeric stabilization foil and the rear side polymeric stabilization foil are cut in a common cutting action using the laser beam.

17. Method according to claim 15,
wherein the front side polymeric stabilization foil and the rear side polymeric stabilization foil each consist of a polymeric material,
wherein the laser beam is applied with physical characteristics which are selected such that, in the step of cutting, the front side polymeric stabilization foil and the rear side polymeric stabilization foil are temporarily heated to a maximum temperature in an area adjoining a cutting edge due to energy applied by the laser beam, the maximum temperature being between a glass transition temperature and an autoignition temperature of the polymeric material of at least one of the front side polymeric stabilization foil and the rear side polymeric stabilization foil.

18. Method according to claim 15,
wherein the front side polymeric stabilization foil and the rear side polymeric stabilization foil each consist of a polymeric material,
wherein the laser beam is applied with physical characteristics which are selected such that, in the step of cutting, the front side polymeric stabilization foil and the rear side polymeric stabilization foil are temporarily heated to a maximum temperature in an area adjoining a cutting edge due to energy applied by the laser beam, the maximum temperature being between a glass transition temperature and a melting temperature of the polymeric material of at least one of the front side polymeric stabilization foil and the rear side polymeric stabilization foil.

19. Method according to claim 15, wherein the intermediate product photovoltaic label is cut using the laser beam such as to form the photovoltaic label with final dimensions with a lateral tolerance of less than 1 mm with regards to predefined dimensions.

20. Method according to claim 15,
wherein at least one of the front side polymeric stabilization foil and the rear side polymeric stabilization foil comprises at least one marker, and
wherein, during the step of cutting, the laser beam is guided with reference to the at least one marker.

21. Method according to claim 15, wherein the photovoltaic cells included in the solar cell arrangement are wafer-based silicon photovoltaic cells.

22. Method according to claim 15, wherein the front side polymeric stabilization foil and the rear side polymeric stabilization foil have different physical characteristics.

23. Method according to claim 15, wherein the front side polymeric stabilization foil and the rear side polymeric stabilization foil have different thicknesses.

24. Method according to claim 15, wherein the front side polymeric stabilization foil and the rear side polymeric stabilization foil comprise different materials.

25. Method according to claim 15, wherein, in the step of joining, the front side polymeric stabilization foil, the rear side polymeric stabilization foil and the solar cell arrangement are joined together by at least one of an application of heat and a lamination process.

26. Method for fabricating a photovoltaic module, the method comprising:
at least one of preparing a photovoltaic label in accordance with a method as claimed in claim 15 and providing a photovoltaic label being prepared in accordance with a method as claimed in claim 15, and
preparing a carrier structure for carrying the photovoltaic label,
wherein the carrier structure is prepared with a polymer being in a mouldable condition such that the polymer forms a positive substance jointing with the rear side polymeric stabilization foil upon solidifying of the polymer.

27. Method of claim 26,
wherein, upon the preparing of the carrier structure, the polymer being in the mouldable condition is injected into a mould,
wherein the mould comprises a recess having recess dimensions, and
wherein, upon the preparing of the carrier structure, the photovoltaic label is arranged in the recess of the mould after having been cut to the final dimensions during the preparing of the photovoltaic label, the final dimensions being equal or less than 1 mm smaller than the recess dimensions.

28. Method of claim 26,
wherein, upon the preparing of the carrier structure, the polymer in its mouldable condition is applied to the photovoltaic label exclusively at an exposed surface of the rear side polymeric stabilization foil.
